(19) United States
(12) Patent Application Publication
(10) Pub. No.: US 2003/0054583 A1
(43) Pub. Date: Mar. 20, 2003

(54) Method for producing an image sensor assembly

(75) Inventors: Jaime I. Waldman, Pittsford, NY (US); Mario Ciminelli, Rochester, NY (US); Michael A. Marcus, Honeoye Falls, NY (US)

Correspondence Address: Thomas H. Close, Patent Legal Staff, Eastman Kodak Company, 343 State Street, Rochester, NY, 14650-2201, US

(73) Assignee: Eastman Kodak Company

(21) Appl. No.: 09/957,188

(22) Filed: Sep. 20, 2001

(51) Int. Cl. H01L 21/00

(52) U.S. Cl. 438/48

(57) ABSTRACT

A method for producing an image sensor assembly, the method comprises the steps of providing a substrate having a substantially flat surface; providing a lead frame having a plurality of lead prongs extending therefrom and a shelf on which a coverglass may be attached; attaching an imager for collecting incident light to the substantially flat surface with an adhesive substance that adheres without thermal activation; and attaching the imager to a portion of the lead frame with an adhesive substance that adheres without thermal activation for producing an image sensor assembly.

### FIELD OF THE INVENTION

The invention relates generally to the field of image sensors and, more particularly, to such image sensors that are assembled in a cavity package in a substantially flat position for improved image capture.

### BACKGROUND OF THE INVENTION

Large area imagers, CCDs and CMOS, are required to be flat to capture a quality image. For many applications, it is required that large area imagers (50 mm by 50 mm) be held to a surface of better than 15 microns. Currently, these imagers are mounted on either a flat substrate or mounted in an electronic package. In the case of a mounted substrate, there isn't a method to protect the bond wires, mount the coverglass and prevent moisture/contamination egress onto the sensor without adding additional structural components. As for all currently available electronic packages, the flatness for the ceramic or brazed heat sink types do not meet the required flatness specifications.

Although the currently known and utilized methods for producing an image sensor assembly are satisfactory, they include drawbacks. The mounted substrates do not have sufficient flatness after the brazing process for imagers requiring high image capture. In addition, the flat substrates are not enclosed which obviously limits their ability to mount optical coverglass or protect the sensor and wire bonds.

### SUMMARY OF THE INVENTION

The present invention is directed to overcoming one or more of the problems set forth above. Briefly summarized, according to one aspect of the present invention, the invention resides in a method for producing an image sensor assembly, the method comprising the steps of (a) providing a substrate having a substantially flat surface; (b) providing a lead frame having a plurality of lead prongs extending therefrom and a shelf on which a coverglass may be attached; (c) attaching an imager for collecting incident light to the substantially flat surface with an adhesive substance that adheres without thermal activation; and (d) attaching the imager to a portion of the lead frame with an adhesive substance that adheres without thermal activation for producing an image sensor assembly.

These and other aspects, objects, features and advantages of the present invention will be more clearly understood and appreciated from a review of the following detailed description of the preferred embodiments and appended claims, and by reference to the accompanying drawings.

### ADVANTAGEOUS EFFECT OF THE INVENTION

The present invention has the following advantage of providing an image assembly that is substantially flat when installed while including a shelf on which a coverglass may be attached. The assembly provides a method to protect the bond wires, mount the coverglass and prevent moisture/contamination egress onto the sensor without additional structural components.

### BRIEF DESCRIPTION OF THE DRAWINGS

FIG. 1 is a view in vertical cross section of the image assembly of the present invention;

FIG. 2 is a view in vertical cross section of an alternative embodiment of FIG. 1; and

FIG. 3 is a view in vertical cross section of another alternative embodiment of FIG. 1.

### DETAILED DESCRIPTION OF THE INVENTION

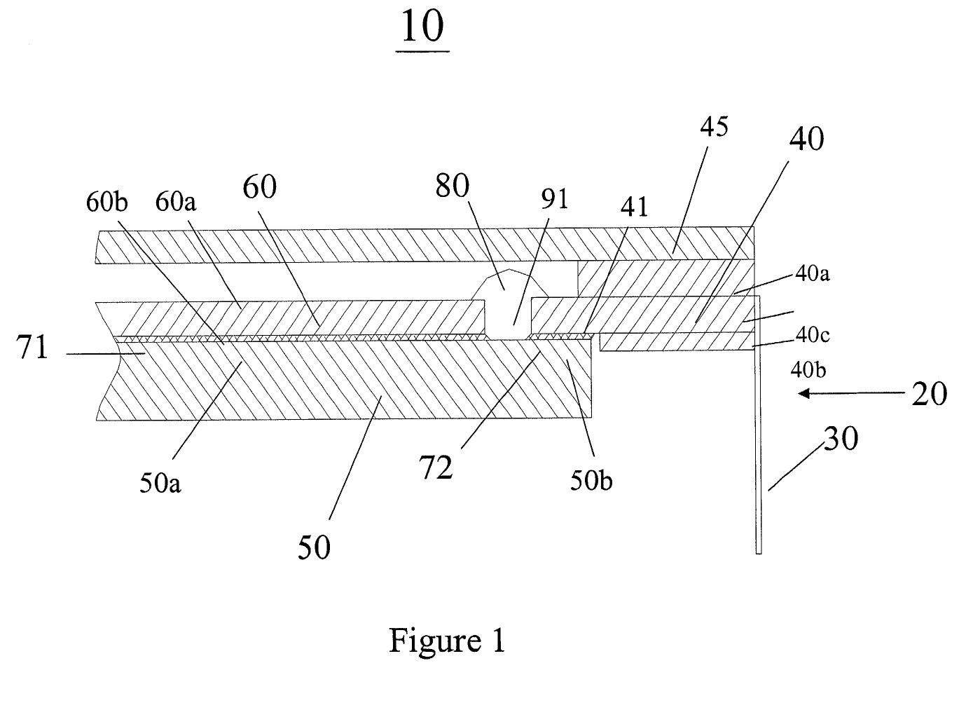

Referring to FIG. 1, the present invention will be described showing only the right most portions of a packaged imager 10 and it is to be understood that an exact duplicate portion or mirror image of this portion is on the left portion. Furthermore, in the following description, like reference characters designate like or corresponding parts throughout the several views of the drawings. Also in the following description, it is to be understood that such terms as “top,” “bottom,” “left,” “right,” “upwardly,” “downwardly,” and the like are words of convenience and are not to be constructed as limiting terms.

The present invention includes a lead frame 20 having a plurality of lead prongs 30 (only one is shown) along its edge which are electrically insulated from each other, and which extend from and are attached to a rectangular shaped frame portion 40 forming a hollowed-out portion into which a suitable imager is to be inserted. The frame portion 40 is a multi-tiered portion extending substantially perpendicular to the lead prongs. The frame portion 40 of lead frame 20 is shown to have three tiers (or layers), although it is to be understood that more or less tiers could be used and each of these tiers may be made up of more than one layer. The top tier 40a provides a shelf for affixing a coverglass 45 to enclose the imager assembly. The middle tier 40b is slightly longer then the top tier 40a and it contains metallization such as traces and bond pads used to provide a means of electrically connecting the imager 60 to the lead prongs 30. The bottom portion 40c is used to provide mechanical features for precisely locating the substrate and imager 60 within the lead frame 20.

A top surface 50a of a substrate 50 is ground or produced substantially flat, and an imager 60 (such as silicon die) with an active imager surface 60a and an imager bonding surface 60b is affixed atop the flat surface 50a of the substrate 50 at the imager bonding surface 60b by a first adhesive layer 71, such as epoxy, which is located between the two surfaces 50a and 60b. A second adhesive layer 72, such as epoxy, is placed between the bonding surface of the substrate 50b and the bonding surface 41 of the frame portion 40.

Bond wires 80 are then attached over the upper gap region 91 between the imager 60 and middle tier 40b for electrically connecting the two together. As mentioned above, the coverglass 45 is then placed atop the top tier 40a for enclosing the image assembly. The coverglass may or may not incorporate optical characteristics to provide enhanced imaging. The coverglass may also utilize an epoxy light shield to block unwanted light from impinging on the wire bonds thus creating spurious illumination onto the imager, as illustrated in U.S. Pat. No. 6,075,237.

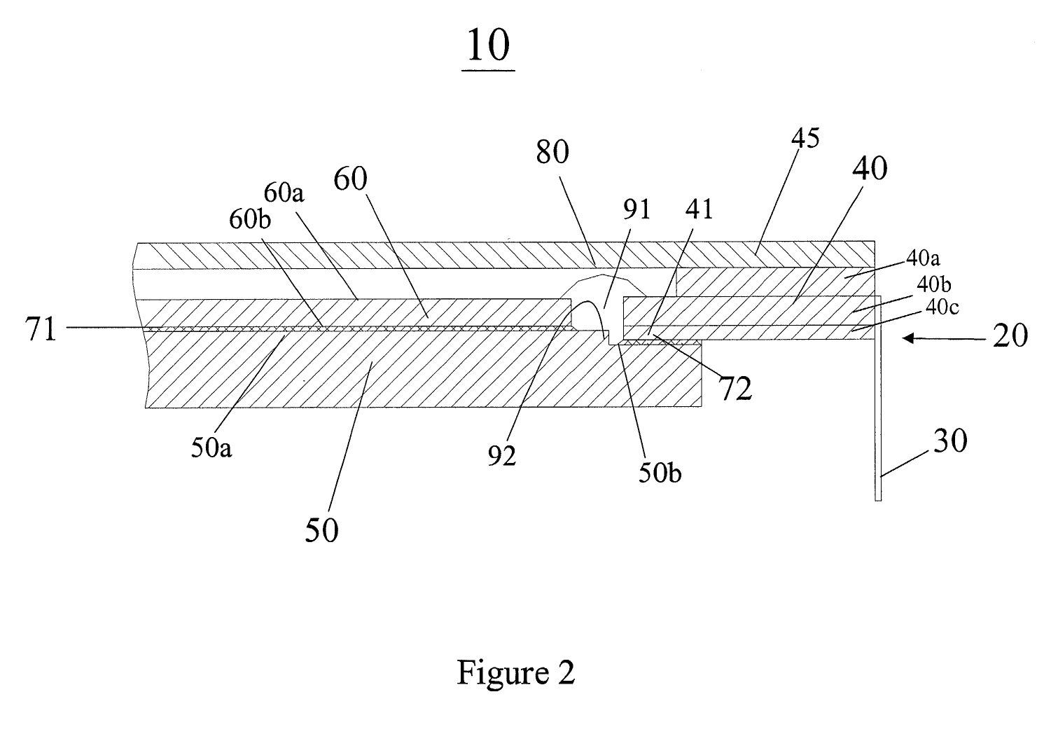

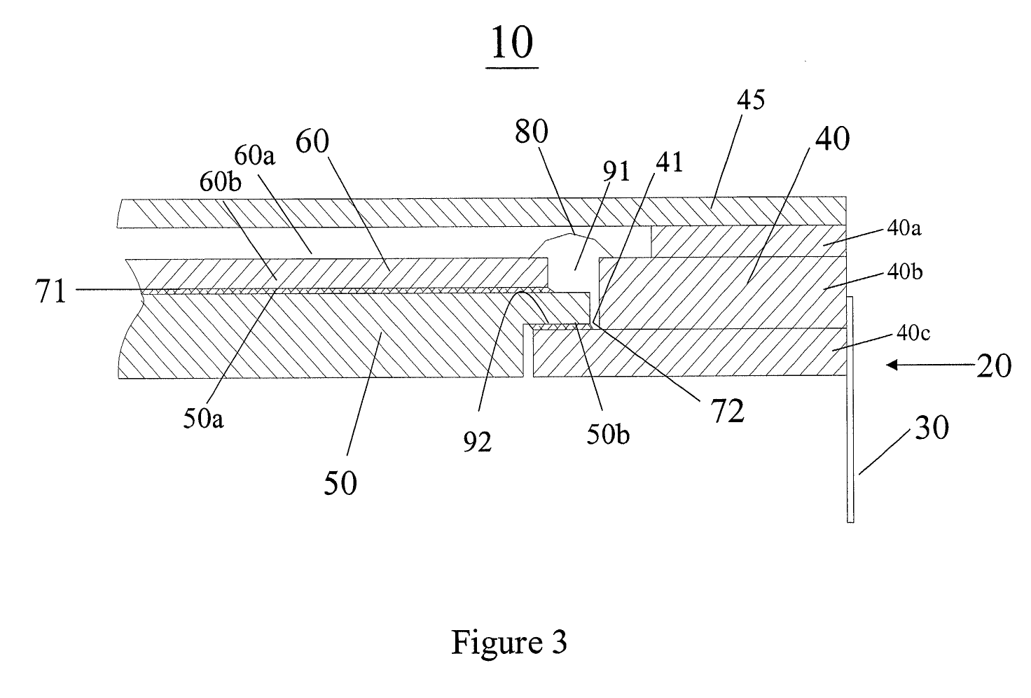

Referring to FIG., 2, there is shown an alternative embodiment of FIG. 1. This embodiment is the same as FIG. 1 except for the inclusion of a step 92 for locating and/or constraining it within the lead frame. Referring to FIG. 3, there is shown still another alternative embodiment of FIG. 1. In this embodiment, the step 92 is inverted from the position of FIG. 2, and it performs the same functions.

The invention has been described in detail with particular reference to certain preferred embodiments thereof, but it will be understood that variations and modifications can be effected within the spirit and scope of the invention.

### Parts List

10 packaged imager

20 lead frame

30 lead prongs

40 frame portion

40a top tier of frame portion

40b middle tier portion of frame portion

40c bottom tier of frame portion

50 substrate

50a top surface of substrate

50b bonding surface of substrate

60 imager

60a imager active surface

60b imager bonding surface

71 first adhesive layer

72 second adhesive layer

80 wire bonds

91 upper gap region

92 step

What is claimed is:

1. A method for producing an image sensor assembly, the method comprising the steps of:
(a) providing a substrate having a substantially flat surface;
(b) providing a lead frame having a plurality of lead prongs extending therefrom;
(c) attaching an imager for collecting incident light to the substantially flat surface with an adhesive substance; and
(d) attaching the imager to a portion of the lead frame with an adhesive substance that adheres without thermal activation for producing an image sensor assembly.

2. The method as in claim 1, wherein step (d) includes attaching the imager to the lead frame with epoxy.

3. The method as in claim 2, wherein step (c) includes attaching the imager to the substantially flat surface with epoxy.

4. The method as in claim 3, wherein step (a) includes providing silicon die as the imager.

5. The method as in claim 4, wherein step (b) includes providing a substantially rectangular shaped lead frame.

6. The method as in claim 1 further comprising providing an active surface area that is flat to better than 15 microns.

7. The method as in claim 1 further comprising providing an alignment mechanism for precisely locating the substrate within the lead frame.
